(19) United States
(12) Patent Application Publication
(10) Pub. No.: US 2005/0112858 A1
(43) Pub. Date: May 26, 2005

(54) Contact hole forming method

(75) Inventors: Han-Ming Yuan, Taipei (TW); Yi-Nan Chen, Taipei (TW)

Correspondence Address: BACON & THOMAS, PLLC, 625 SLATERS LANE, FOURTH FLOOR, ALEXANDRIA, VA, 22314, US

(73) Assignee: NANYA Technology Corporation, Taoyuan (TW)

(21) Appl. No.: 10/717,582

(22) Filed: Nov. 21, 2003

(51) Int. Cl. H01L 21/44

(52) U.S. Cl. 438/597

(57) ABSTRACT

Disclosed is a contact hole forming method for forming gate contact holes and non-gate contact holes. The method of this invention comprises the steps of providing a substrate; forming a plurality of operation layers on the substrate as required, wherein the operation layers of the gate contact hole forming portion comprise at least a gate metal and a cap nitride layer on the gate metal; forming an additional nitride layer on the uppermost layer of the operation layers; forming photoresist on the additional nitride layer to define the positions of the respective contact holes to be formed; forming the non-gate contact hole and removing the portion of the operation layers corresponding to the gate contact hole forming position above the cap nitride by etching; filling the non-gate contact hole with photoresist; and forming the gate contact hole through removing the cap nitride portion corresponding to the gate contact hole forming position and removing all the additional nitride layer by etching.

### BACKGROUND OF THE INVENTION

1. Field of the Invention

This invention relates to semiconductor integrated circuit device manufacturing process, more specifically, to a method for forming a contact hole in a semiconductor integrated circuit device.

2. Description of the Prior Art

In the manufacturing process for semiconductor integrated circuits such as DRAMs, the formation of contact holes plays an important role in the concerned techniques. For example, the contact holes of a DRAM device include bit line contact holes, substrate contact holes and gate contact holes.

FIG. 1a illustrates a sectional schematic diagram of a DRAM structure to be formed with contact holes in prior art. In this drawing, a portion to be formed into a bit line contact hole (CB), a portion to be formed into a substrate contact hole (CS) and a portion to be formed into a gate contact hole (CG) are shown. In the portion to be formed into the bit line contact hole (CB), reference number 10 indicates a substrate of silicon, 11 indicates a pad nitride layer, 12 indicate bit line regions, 13 is a dielectric layer, the material of which can be boron phosphorus silicon glass (BPSG), filled between the bit line regions 12 and 14 is an oxide layer, the material of which can be TEOS, on the dielectric layer 13 and the bit line regions 12. A thin conducting layer 15, which can be a poly-silicon layer, is formed on the oxide layer 14. Finally, photoresist 16 is applied to define a position to be formed into a bit line contact hole CB. In the portion to be formed into a substrate contact hole CS, the pad nitride layer 11 is formed on the substrate 10. The dielectric layer 13, oxide layer 14 and thin poly-silicon layer 15 are formed on the pad nitride layer 11. The photoresist 16 is formed to define a position to be formed into the substrate contact hole CS. In the portion to be formed into a gate contact hole CG, a conducting layer 17, such as a poly-silicon layer, is formed on the substrate 10. The reference number 18 indicates the gate metal, the material of which can be tungsten silicide. A cap nitride layer 19 is formed on the gate metal 18, and the oxide layer 14 and the thin poly-silicon layer 15 are formed on the cap nitride 19. The photoresist 16 is formed to define a position to be formed into the gate contact hole CG. The relevant steps of the process are all known in this field, and therefore the descriptions thereof are omitted for simplification.

After the structure of FIG. 1a is etched and the photoresist 16 is removed, the obtained structure is shown in FIG. 1b. As shown in this drawing, in the portion to be formed into the gate contact hole, because the cap nitride layer 19 acts as an etch stop layer, the depth of the etched hole fails to reach the gate metal 18.

In order to further removing the corresponding portion of the cap nitride layer 19, a poly hard mask 21 is formed on the portion to be formed into the gate contact hole CG, as shown in FIG. 2. Then, a further etch is performed to remove the corresponding portion of the cap nitride 19, so that the opened contact hole CG reaches the gate metal 18. Finally, the hard mask 21 is removed, as shown in FIG. 3.

However, because to the refraction index of the material of the poly hard mask is very high, causing the developing and imaging not good, it is difficult to detect alignment marks in the step shown in FIG. 2. Therefore, additional alignment marks for development and etch steps and so on are needed.

Therefore, a solution to solve the above problems is necessary. The present invention satisfies such a need.

### SUMMARY OF THE INVENTION

An objective of the present invention is to provide a novel contact hole forming method, which can avoid using the poly hard mask so as to eliminate the need for additional alignment mark developing and etching steps.

According to one aspect of the present invention, a gate contact hole and non-gate contact hole forming method comprises the steps of providing a substrate; forming a plurality of necessary operation layers on the substrate, wherein the operation layers at the portion to be formed into a gate contact hole include at least a gate metal and a cap nitride layer formed on the gate metal; forming a nitride layer on the uppermost layer of the operation layers; forming photoresist on the nitride layer to define positions to be formed into the respective contact holes; removing a portion of each operation layer corresponding to the position to be formed into a non-gate contact hole to form a non-gate contact hole and removing a portion of each operation layer above the cap nitride layer corresponding to the position to be formed into a gate contact hole; filling the non-gate contact hole with photoresist; and removing a portion of the cap nitride layer corresponding to the position to be formed into the gate contact hole to form a gate contact hole and removing unnecessary portion of the nitride layer.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIGS. 1a and 1b are sectional schematic diagrams showing the respective steps of a contact hole forming method in prior art;

FIG. 2 is a sectional schematic diagram showing the structure in the step of using poly hard mask in the gate contact hole forming method according to the prior art;

FIG. 3 is a sectional schematic diagram showing the structure of FIG. 2 with the gate contact hole formed; and

FIGS. 4a to 4f are sectional schematic diagrams showing the respective steps of a contact hole forming method in accordance with the present invention.

### DETIALED DESCRIPTION OF THE PREFERRED EMBODIMENT

A method of the present invention will be described in detail with reference to the accompanying drawings as follows.

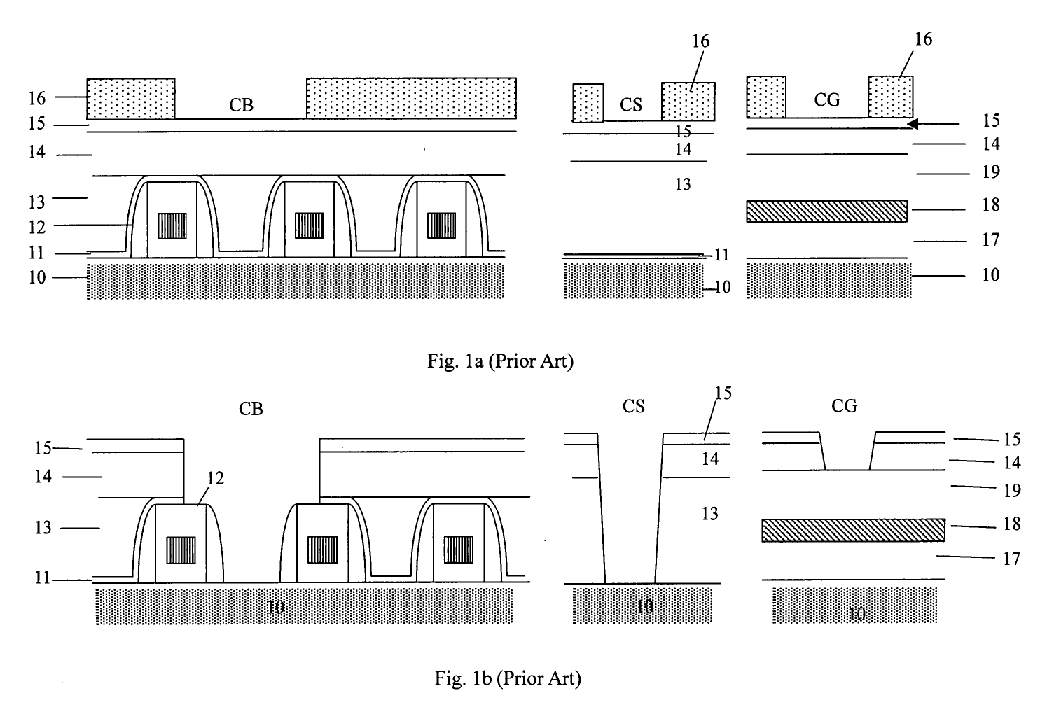

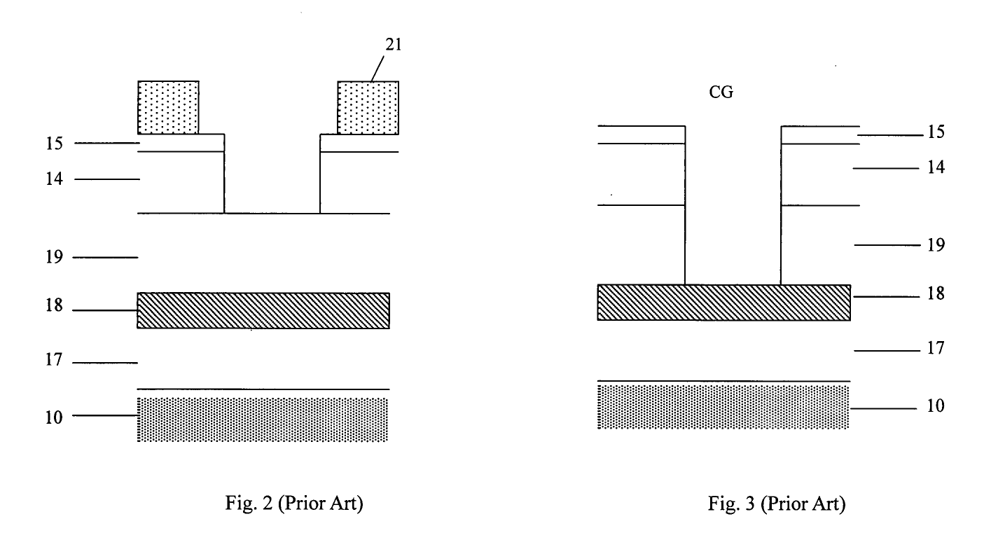

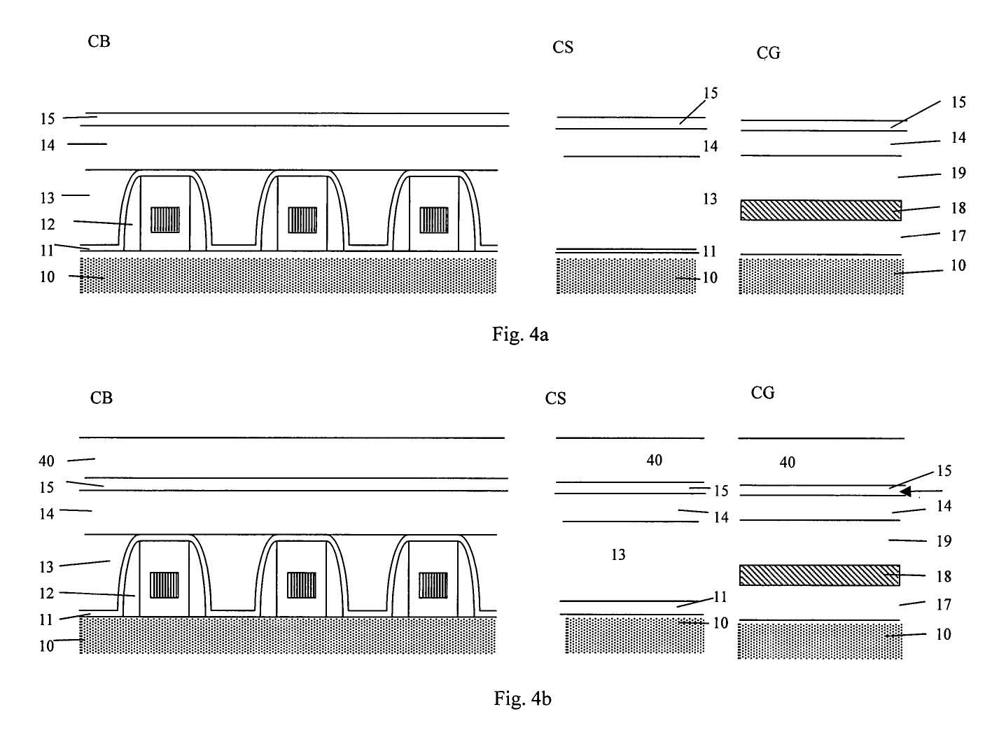

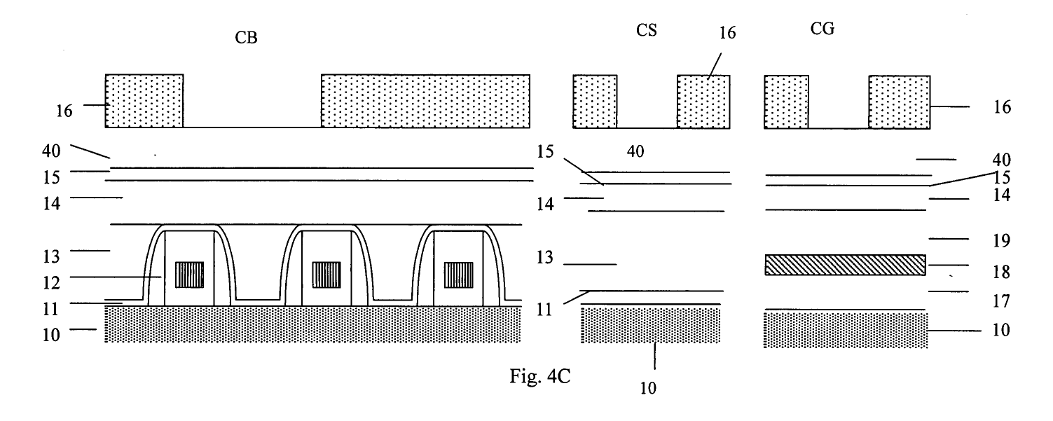

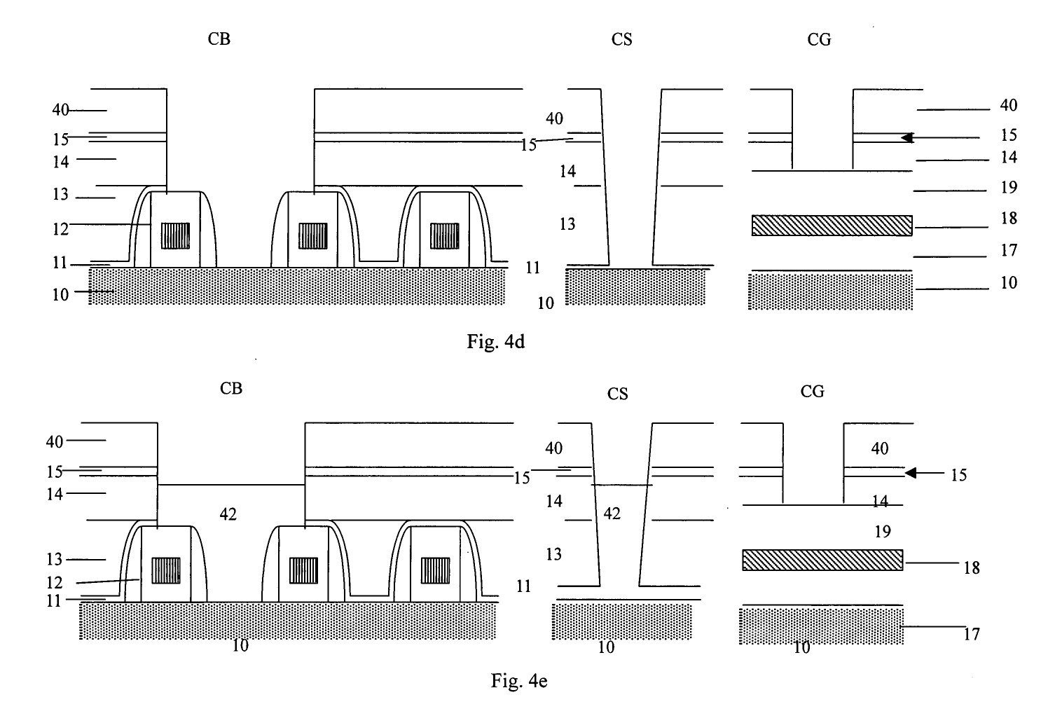

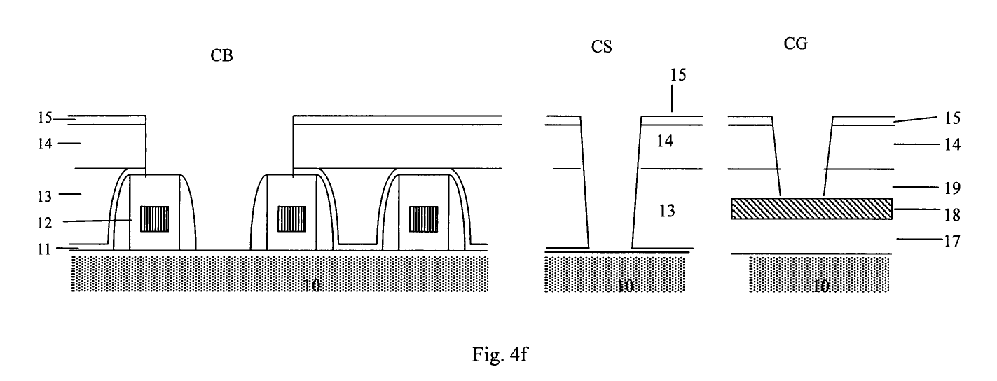

With reference to FIG. 4, wherein the same reference numbers as in FIGS. 1a and 1b indicate the identical parts, and the relevant description will be omitted herein.

The structure shown in FIG. 4a is substantially the same as that in FIG. 1a. Respective operation layers, such as bit line region, gate metal, pad nitride layer, dielectric layer, poly-silicon layer, cap nitride layer, oxide layer, thin poly-silicon layer and the like, are formed on the silicon substrate. The only difference is that the structure shown in FIG. 4a has no photoresist formed thereon. Before forming the photoresist, an additional nitride layer 40 is formed on the thin poly-silicon layer 15, as shown in FIG. 4b. Next, photoresist 16 is formed on the additional nitride layer 40 to define the positions to be formed into the respective contact holes, as shown in FIG. 4c.

Subsequently, etching is performed. At the portion to be formed into a bit line contact hole CB and the portion to be formed into a substrate contact hole CS, the portions of the nitride layer 40, thin poly-silicon layer 15, oxide layer 14 and dielectric layer 13 not covered with the photoresist 16 are etched off. At the portion to be formed into a gate contact hole CG, since there is the cap nitride layer 19 acting as an etch stop, the etching process is stopped at the oxide layer 14. The structure after the etching process is finished and the photoresist is removed is shown in FIG. 4d. In the drawing, the bit line contact hole CB and the substrate contact hole CS are formed.

Hereinafter, as shown in FIG. 4e, the bit line contact hole CB and the substrate contact hole CS are filled with photoresist 42 to protect the dielectric layer 13 and oxide layer 14 from being eroded in the subsequent etching step.

Finally, a portion of the cap nitride layer 19 corresponding to the position to be formed into the gate contact hole CG is removed by proper etching process to form the gate contact hole CG. Simultaneously, in the same etching step, the additional nitride layer 40 covering the thin poly-silicon 15 is also removed, as shown in FIG. 4f.

In the method in accordance with the present invention, due to the function of the additional nitride layer 40, it is not necessary to use poly hard mask, thereby avoiding the problems caused by using the poly hard mask with high refraction index in prior art.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A contact hole forming method comprising the steps of:
providing a substrate;
forming a plurality of proper operation layers as required on said substrate;
forming a nitride layer on the uppermost layer of said operation layers;
forming photoresist on said nitride layer to define a position to be formed into a contact hole;
forming the contact hole by etching; and
removing said nitride layer.

2. The method as claimed in claim 1, wherein the step of removing said nitride layer is performed by etching, and a corresponding portion of one of said operation layers not removed in the step of forming the contact hole is removed simultaneously.

3. The method as claimed in claim 2, wherein said one of said operation layers, of which the corresponding portion is not removed in the step of forming the contact hole, is a nitride layer.

4. The method as claimed in claim 3, wherein said one of said operation layers, of which the corresponding portion is not removed in the step of forming the contact hole, is a cap nitride layer for a gate electrode.

5. The method as claimed in claim 1, further comprising a step of using photoresist to protect portions not to be eroded in said step of removing said nitride layer before the removing step.

6. A gate contact hole forming method comprising the steps of:
providing a substrate;
forming a conducting layer on said substrate;
forming a gate metal on said conducting layer;
forming a cap nitride on said gate metal;
forming an oxide layer on said cap nitride;
forming a thin conducting layer on said oxide layer;
forming an additional nitride layer on said thin conducting layer;
forming photoresist on said additional nitride layer to define a position to be formed into a gate contact layer;
removing portions of said additional nitride layer, thin conducting layer and oxide layer corresponding to the position to be formed into the gate contact hole, and then removing the photoresist; and
removing a portion of said cap nitride corresponding to the position to be formed into the gate contact hole, and removing the additional nitride layer.

7. The method as claimed in claim 6, wherein said conducting layer is a poly-silicon layer.

8. The method as claimed in claim 6, wherein said thin conducting layer is a thin poly-silicon layer.

9. A method for forming contact holes including a gate contact hole and a non-gate contact hole, said method comprising steps of:
providing a substrate;
forming a plurality of operation layers on said substrate, the operation layers at the portion to be formed into the gate contact hole including at least a gate metal and a cap nitride layer formed on the gate metal;
forming a nitride layer on the upper most layer of the operation layers;
forming photoresist on said nitride layer to define positions to be formed into the respective contact holes;
removing portions of the respective operation layers corresponding to the position to be formed into the non-gate contact hole to form the non-gate contact hole and removing portions of the operation layers above the cap nitride layer corresponding to the position to be formed into the gate contact hole;
filling the non-gate contact hole with photoresist; and
removing the portion of the cap nitride layer corresponding to the position to be formed into the gate contact hole to form the gate contact hole and removing said nitride layer.
